(19) United States
(12) Patent Application Publication
(10) Pub. No.: US 2019/0198421 A1
(43) Pub. Date: Jun. 27, 2019

(54) HEAT RADIATING PLATE-LINED CERAMICS SUBSTRATE

(71) Applicant: KABUSHIKI KAISHA TOSHIBA, Minato-ku (JP)

(72) Inventors: Masahiro Yokota, Fukaya (JP); Akihiko Happoya, Yokohama (JP)

(73) Assignee: KABUSHIKI KAISHA TOSHIBA, Minato-ku (JP)

(21) Appl. No.: 15/920,626

(22) Filed: Mar. 14, 2018

Related U.S. Application Data
(60) Provisional application No. 62/610,698, filed on Dec. 27, 2017.

(51) Int. Cl. H01L 23/373; C23C 18/18; C23C 18/32; C25D 3/38; C23F 17/00; B32B 15/20; B32B 15/04

(52) U.S. Cl. CPC H01L 23/3735; C23C 18/1882; C23C 18/32; B32B 15/04; C23F 17/00; B32B 15/20; C25D 3/38

(57) ABSTRACT

According to one embodiment, a heat radiating plate-lined ceramic substrate includes a first bonding layer, a plating layer and a heat radiating plate provided in order on the ceramic substrate. The first bonding layer is formed from a molecular bonding material containing a ceramic substrate fixing portion and a plating support portion. The ceramic substrate fixing portion and the first bonding layer are bonded together by the ceramic substrate fixing portion and the plating layer and the first bonding layer are bonded together by the plating support portion.

### CROSS-REFERENCE TO RELATED APPLICATIONS

This application claims the benefit of U.S. Provisional Application No. 62/610,698, filed Dec. 27, 2017, the entire contents of which are incorporated herein by reference.

### FIELD

Embodiments described herein relate generally to a heat radiating plate-lined ceramics substrate.

### BACKGROUND

For power semiconductor modules, ceramic substrates with high thermal conductivity, such as of aluminum nitride or silicon nitride, are used for insulation and heat radiation.

When a semiconductor, which is a heat generating source, is mounted on a heat radiating plate formed of, for example, Cu or Al, the generated heat is diffused in a large area. On the other hand, the heat radiating plate is welded to a ceramic substrate, which is an insulator, by using a solder or a brazing filler metal, and the diffused heat is radiated to the heat radiating unit through the ceramic substrate. A ceramic substrate is a thin board having a sufficient area and a creeping pressure resistance, and its semiconductor and electrodes are usually sealed with a resin. The heat radiating unit is formed of Cu or Al, which can radiate heat by water-cooling or air-cooling.

In terms of the modular structure, the heat radiating plate may be integrated with a semiconductor as one unit, or the heat radiating plate may be partially omitted, or the heat radiating unit may be omitted.

Conventionally, in such a ceramic substrate, the thermal conductivity is improved while retaining the insulation of the substrate. Further, the thermal resistance is decreased by further thinning the ceramic substrate, and the contact heat conduction in an interface between the ceramic substrate and the thermal conductive diffusion plate is reduced by welding them together using solder or a brazing filler metal.

### BRIEF DESCRIPTION OF THE DRAWINGS

FIG. 1 is a schematic cross-sectional view showing a structure of a heat radiating plate-lined ceramic substrate according to the first embodiment.

FIG. 2 is a schematic cross-sectional view showing the structure of a power semiconductor module employing the heat radiating plate-lined ceramic substrate shown in FIG. 1.

FIG. 3 is a schematic cross-sectional view showing an example of the structure of a heat radiating plate-lined ceramic substrate according to the second embodiment.

FIG. 4 is a schematic cross-sectional view showing an example of the structure of a heat radiating plate-lined ceramic substrate according to the third embodiment.

FIG. 5 is a schematic cross-sectional view showing an example of the structure of a heat radiating plate-lined ceramic substrate according to the fourth embodiment.

FIG. 6 is a diagram showing a pattern of a first bonding layer used in the fourth embodiment.

FIG. 7 is a diagram showing a state of the ceramic substrate and a plating layer used in the fourth embodiment.

FIG. 8 is a schematic cross-sectional view showing an example of the structure of a heat radiating plate-lined ceramic substrate according to the fifth embodiment.

FIG. 9 is a schematic cross-sectional view showing an example of the structure of a heat radiating plate-lined ceramic substrate according to the sixth embodiment.

FIG. 10A, FIG. 10B, FIG. 10C, FIG. 10D, and FIG. 10E each illustrate an example of a step in a manufacturing process of the heat radiating plate-lined ceramic substrate according to the first embodiment shown in FIG. 1.

FIG. 11A and FIG. 11B are diagrams each illustrating a step in a manufacturing process of the head radiating plate-lined ceramic substrate according to the second embodiment shown in FIG. 3.

### DETAILED DESCRIPTION

In general, according to one embodiment, a heat radiating plate-lined ceramic substrate comprises a ceramic substrate, a first bonding layer provided on the ceramic substrate, a plating layer provided on the first bonding layer and a heat radiating plate provided an the plating layer.

The first bonding layer comprises a molecular bonding material containing a ceramic substrate fixing portion and a plating support portion.

The ceramic substrate and the first bonding layer are bonded together by the ceramic substrate fixing portion, and the heat radiating plate and the first bonding layer are bonded together by the plating support portion.

Hereinafter, embodiments will now be described with reference to drawings.

FIG. 1 is a schematic cross-sectional view showing a structure of the ceramic substrate with a heat radiating plate according to the first embodiment.

As shown, a heat radiating plate-lined ceramic substrate 10 comprises a ceramic substrate 1, a first bonding layer 2 provided on the ceramic substrate 1, a plating layer 3 provided on the first bonding layer 2, a surface of which is flat, a second bonding layer 11 provided on the flattened surface of the plating layer 3, and a heat radiating plate 4 provided on the second bonding layer 11.

In the heat radiating plate-plated ceramic substrate according to the first embodiment, a molecular bonding material is applied in advance on a surface of the ceramic a substrate to form a first bonding layer, and then a plate film is forced thereon. Thereafter, a surface of the plate film is polished to be flattened, and again, a second bonding layer is formed using the molecular bonding material. Then, a heat radiating plate is bonded thereon.

Even if a plating layer is formed on a ceramic substrate by physically placing a catalyst which serves as plating seeds on recess portions of unevenness on the surface of the ceramics, the bonding strength of the plating layer is only expected by the fix effect by the unevenness, and therefore it is difficult in terms of strength load to further provide a heat radiating plate on the plating layer.

On the other hand, in the heat radiating plate-lined ceramic substrate according no the embodiment, the first bonding layer is formed from a molecular bonding material containing a ceramic substrate fixing portion and a plating support portion. Further, the ceramic substrate fixing portion is provided between the ceramic substrate and the first bonding layer to bond them together, and the plating support portion is provided between the plating layer and the first bonding layer to bond them together. With this structure, even if a heat radiating plate is provided further on the plating layer, sufficient strength can be obtained.

The molecular bonding material used in the embodiment will be described.

The molecular bonding material contains a silanol-forming group such as ethoxysilane or methoxysilane in its molecule, which is bonded by hydrogen-bonding to the hydroxyl group of the surface of the ceramic substrate when, for example, impregnating the ceramic substrate into a molecular bonding material solution, and when heat is applied, dehydration condensation occurs thereby forming a strong siloxane bond.

Further, the molecular bonding material comprises a site which bonds a plating catalyst containing nitrogen or sulfur, such as an amino group, an azido group, a triazine ring or a thiol group, in the molecules. It firmly bonds to the plate film grown from the plating catalyst, and further the silanol-forming group is bonded to the plating metal to form a plating support portion.

In the embodiment, the plating layer thus formed is grown to be a thick film, and further the surface thereof is polished to increase the flatness. Similarly, a thermal diffusion conductive plate is polished to increase its flatness. Thus, the thick plating layer and the thermal diffusion conductive plate can be attached together using again the molecular bonding material.

Note that in place of polishing the plated surface, it can be flattened by rolling. As the plating metal, one with high spreadability, for example, Cu is used. Therefore, the plating layer grown to be a thick film can be easily polished. Moreover, the plated surface is pressed with a roller (or a press board) with a polished surface, to reduce the roughness of the surface. Thus, the bonding strength using the molecular bonding material can be improved.

Moreover, for a module on which a certain amount of pressure can be applied, the contact thermal resistance of the interface can be reduced to a certain degree by the flattening process even without providing a second bonding layer between the plating layer and the heat radiating plate.

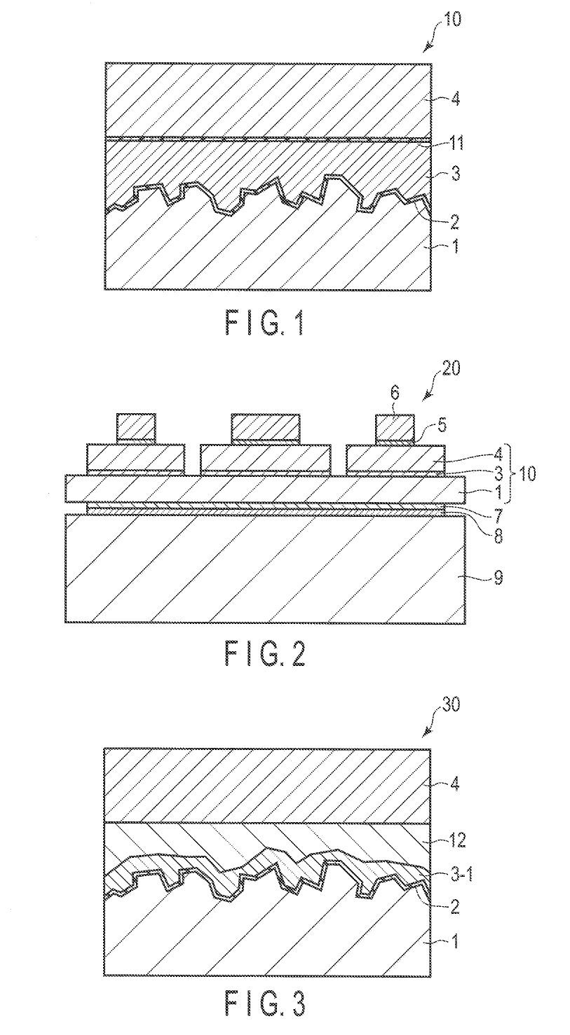

FIG. 2 is a schematic cross-sectional view showing the structure of a power semiconductor module employing the heat radiating plate-lined ceramic substrate shown in FIG. 1.

A power semiconductor module 20 comprises the ceramic substrate 1, the plating layer 3 provided on one main surface of the ceramic substrate 1 via a first bonding layer not illustrated, a plurality of heat radiating plates 4 provided on the plating layer 3, heat radiating parts 6 such as a semiconductor device and electrodes, each provided on the heat radiating plate 4, a plating layer 7 provided on the other main surface of the ceramic substrata 1 via a third bonding layer (not shown), and a heat radiating unit 9 provided on the plating layer 7 via a plating layer 8.

FIG. 3 is a schematic cross-sectional view showing an example of the structure of a heat radiating plate-lined ceramic substrate according to the second embodiment.

As shown, a heat radiating plate-lined ceramic substrate 30 has a structure similar to that shown in FIG. 1 except that a plating layer 3-1 which is thinner than the plating layer 3 and whose surface is not polished and a solder layer 12 located on the plating layer 3-1 are provided between the first bonding layer 2 and the heat radiating plate 4 in place of the plating layer 3 whose surface is flattened and the second bonding layer 11.

Here, the plating layer can be formed by electroless plating of, for example, Ni or Ni+Sn(Au), and the heat radiating plate can be welded with solder. By using the electroless plating, the material and its thickness can be selected in consideration of corrosion by soldering, and the material can be formed thinner if needed in consideration of the solder wettability of the surface and corrosion during the handling thereof.

With such a structure, when the production line of the heat radiating plate-lined ceramic substrate includes a solder-welding step, the reliability of the bond between the ceramic substrate and the solder layer 12 can be ensured by the molecular bonding by the first bonding layer 2 to the plating layer 3-1, and the solder wettability of the plating layer 3-1 while utilizing the facilities.

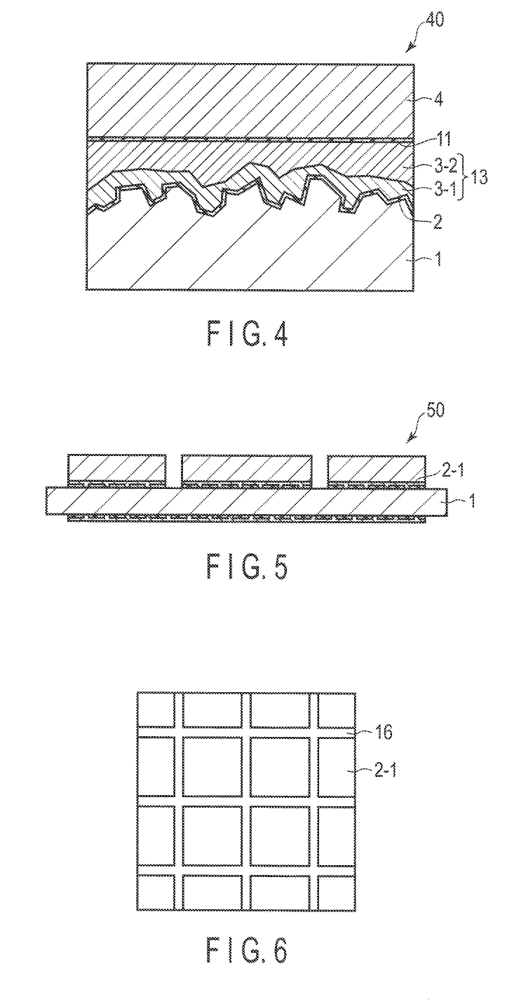

FIG. 4 is a schematic cross-sectional view showing an example of the structure of a heat radiating plate-lined ceramic substrate according to the third embodiment.

As shown, a heat radiating plate-lined ceramic substrate 40 has a structure similar to that shown in FIG. 1 except that a multi-layered plating layer 13 including a plating layer 3-1 which is thinner than the plating layer 3 and whose surface is not polished and a plating layer 3-2 located on the plating layer 3-1 and whose surface is polished is provided between the first bonding layer 2 and the heat radiating plate 4 in place of the plating layer 3 whose surface is flattened and the second bonding layer 11.

Here, the plating layer can be formed from double layers, in which one plating layer 3-1 on a ceramic substrate side is formed of a plating metal of, for example, Cu, whereas the other plating layer 3-2 is formed of a plating metal of, for example, Cr. Plating lamination is comparatively easy to carry out, in which one or more layers of, for example, Ni or W, can be further added, as needed to prepare three or more layers.

The uppermost plating layer 3-2 is subjected to a flattening process similar to that of the plating layer 3 used in the first embodiment, and thus a heat radiating plate can be bonded thereto with the molecular bonding material.

Many of the ceramic substrates are of low-thermal-expansion materials (for example, AlN has 4 to 5×10⁻⁶/K and Si₃N₄ has 2 to 3×10⁻⁶/K), whereas thermal diffusion conductive plates are of high-thermal expansion materials (for example, Cu has 17×10⁻⁶/K and Al has 23×10⁻⁶/K). Here, in order to ease the thermal stress caused by the difference in thermal expansion coefficient and the difference in temperature of the operation environment, the plating layer is prepared to a multilayered structure, thereby the thermal expansion coefficient thereof gradually becomes close to those of the ceramic substrate and the thermal diffusion conductive plate.

In the above-described structure, when the lower layer plating layer 3-1 is Cr, the thermal expansion coefficient is 7 (10⁻⁶K), whereas when the upper plating layer 3-2 is Cu, it is 17 (10⁻⁶/K). Thus, the thermal expansion coefficient can be improved in the upper layer as compared to the lower layer.

Similarly, the number of layers in the multilayered structure can be increased by further providing W for the lowermost layer, Ni for a middle layer, and the like.

FIG. 5 is a schematic cross-sectional view showing an example of the structure of a heat radiating plate-lined ceramic substrate according to the fourth embodiment.

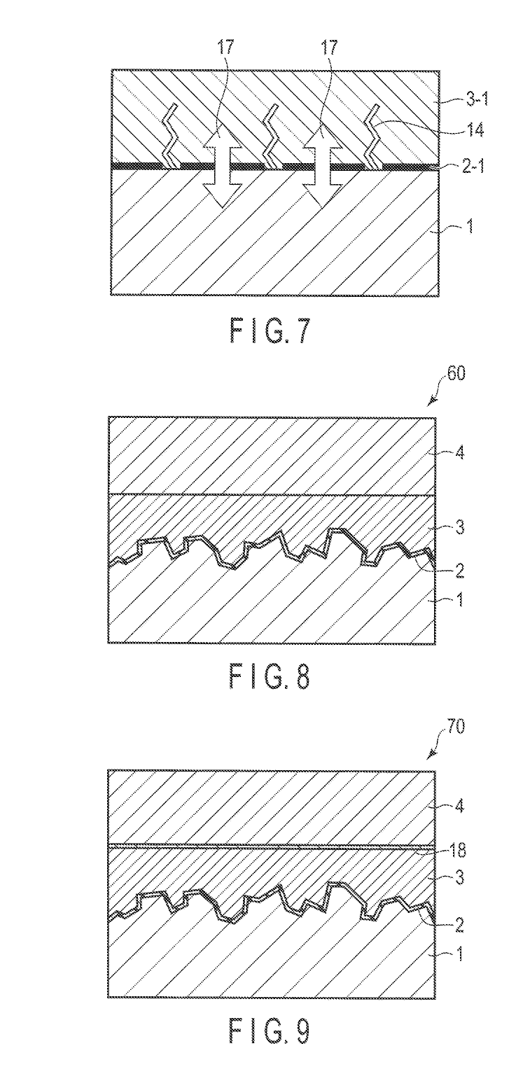

FIG. 6 shows a pattern of the first bonding layer used in the fourth embodiment.

FIG. 7 shows a state of the ceramic substrate and a plating layer used in the fourth embodiment.

A heat radiating plate-lined ceramic substrate 50 comprises a covering layer formed from, for example, a molecular bonding material containing SH group (thiol group), on a ceramic substrate and a first bonding layer 2-1 having such a pattern that the molecular bonding layer is subdivided by a grid-like pattern 16 as shown in FIG. 6. As shown in FIG. 7, on the grid-like pattern 16, gaps 14 are formed as stress release portions to formed by controlled breaking in the plating layer 3. The heat radiating plate is provided on the plating layer 3 having such a structure.

Here, the molecular bonding material can be bound to the ceramic substrate 1 and than the excessive portion of the molecular bonding material can be removed by washing to form the first bonding layer. After that, ultraviolet rays can be irradiated to only the grid-like pattern 16 to deteriorate the SH group of the molecular bonding material located in the grid-like pattern 16 and thus disable the plating catalyst binding capability thereof. Then, for example, Ni electroless plating can be carried out, and thereafter Cu electrolysis plating can be carried out.

In the plating layer 3-1 thus formed, plating cannot be deposited easily from only the portion of the grid-like pattern 16, which has been irradiated with the ultraviolet rays, or even if, deposited, the gaps 14 can be easily formed only in the grid-like pattern 16 because the bonding power between the ceramic substrate 1 and the plating layer 3-1 is weak. Here, let us suppose that the width of the grid-like pattern 16 is, for example, 10 μm. In this case, the portions of the plating layer 3-1 are connected to one another in the grid-like pattern 16 while growing the film to be thicker by electrolysis plating; however the fixing between the surface of the ceramic substrate 1 and the plating layer 3-1 differs in the grid-like pattern 16 as compared to the other sections of the first bonding layer 2-1.

When a temperature cycle load is applied to the heat radiating plate-lined ceramic substrate, the heat transfer between the ceramic substrate 1 and the plating layer 3-1 occurs in the first bonding layer 2-1 between adjacent grid-like patterns 16 as indicated by arrow 17. Therefore, the stress created due to the difference in thermal expansion between the ceramic substrate and the heat radiating plate concentrates in the grid-like patterns 16 of the plating layer 3-1, causing deformation. Thus, the stress is released, thereby preventing exfoliation in the ceramic substrate 50 as a whole.

FIG. 8 is a schematic cross-sectional view showing an example of the structure of a heat radiating plate-lined ceramic substrate according to the fifth embodiment.

As shown, a heat radiating plate-lined ceramic substrate 60 has a structure similar to that shown in FIG. 1 except that the second bonding layer 11 is not provided between the plating layer 3 made flat and the heat radiating plate 4 and the flattened plating layer 3 and the heat radiating plates 4 are bonded together by solid phase diffusion.

The bonding by solid phase diffusion can be carried out by subjecting the polished surface of the plating layer to, for example, Ar plasma treatment, followed by heating and pressurization.

The heat radiating plate-lined ceramic substrate according to the fifth embodiment includes the first bonding layer between the ceramic substrate and the plating layer, by which sufficient bonding strength can be ensured. Further, with the bonding by solid phase diffusion, the thermal resistance between the plating layer 3 and the heat radiating plate 4 can be reduced.

FIG. 9 is a schematic cross-sectional view showing an example of the structure of a heat radiating plate-lined ceramic substrate according to the sixth embodiment.

As shown, a heat radiating plate-lined ceramic substrate 70 has a structure similar to that shown in FIG. 1 except that a thermal stress relaxation layer 18 is formed between the flattened plating layer 3 and the heat radiating plate 4 in place stead of the second bonding layer 11.

The thermal stress relaxation layer can be formed by subjecting a silicone resin containing a high thermal conductive fine filler of, for example, AlN, SiN, Al₂O₃ or BN by 70 to 90% by weight to heating and pressurization. With the bonding by the thermal stress relaxation layer, the thermal resistance is slightly deteriorated, but the thermal stress relaxation layer is distorted, and thus the thermal stress due to the thermal expansion between the plating layer 3 and the heat radiating plate 4 can be relaxed. For example, if the Cu plating layer 3 is applied on the Cu heat radiating plate which is of the same material as the plating layer 3, the plating layer 3 is strongly bonded to the ceramic substrate 1, and also the plating layer 3 is very thin as compared to the entire area; therefore it is substantially distorted in accordance with the thermal expansion of the ceramic substrate. Therefore, the stress caused by the difference in thermal expansion is created between the plating layer 3 and the heat radiating plate 4. Here, by providing a soft thermal stress relaxation layer 18, the thermal stress created in the surroundings can be relaxed as the thermal stress relaxation layer 18 is distorted.

Hereinafter, examples will be provided to explain the embodiment in more detail.

### Example 1

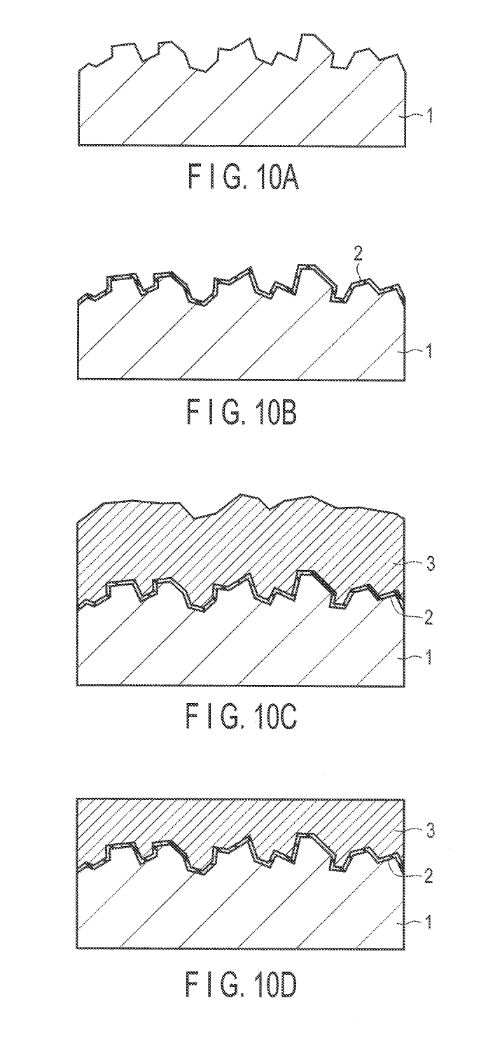

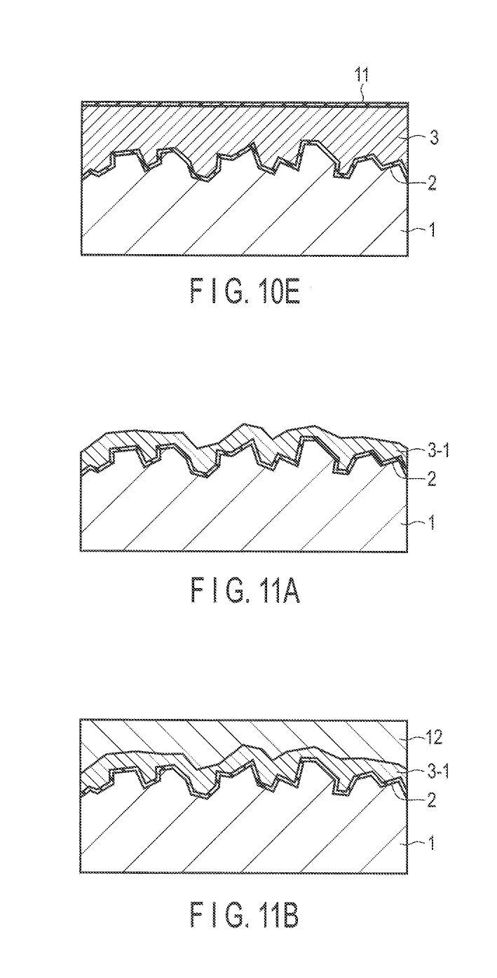

FIGS. 10A to 10E illustrate an example of a process of manufacturing the ceramic substrate according to the first embodiment, which comprises the thermal plate shown in FIG. 1.

As the ceramics substrate 1, for example, Si₃N₄ cab be used and as the heat radiating plate, for example, a Cu plate can be used.

As shown in FIG. 10A, the ceramic substrate 1 can be subjected to a corona discharge treatment after removing the deposits on the surface by washing. Thus, a hydroxyl group is formed on the surface of the ceramic substrate to ensure wettability to an aqueous solution of the molecular bonding material. Further, the hydrogen bonding of the silanol group of the molecular bonding material can be facilitated.

As the molecular bonding material, an aqueous solvent liquid in which a material comprising an ethoxy silane group, an amino group and a triazine ring is dispersed was used. The liquid adjusted to predetermined concentration and molarity was applied to the plate formation area on the ceramic substrate, and dried at 120° C., thereby fixing the first bonding layer 2 formed from the molecular bonding material to the ceramic substrate 1 as shown in FIG. 10B.

Then, the substrate 1 was impregnated into a plating catalyst liquid of Pd colloid for 60 seconds at room temperature, to be dried. Then, with nickel electroless plating and Cu electroless plating, a Ni+Cu plating layer was formed to have a thickness 100 nm and further the plating layer was grown to have a thickness of 10 μm by Cu electrolytic plating, thus obtaining the plating layer 3 as shown in FIG. 10C.

After that, as shown in FIG. 10D, the surface of the plating layer was polished to have a Ra of 0.05 μm.

Furthermore, as shown in FIG. 10E, the entire substrate 1 was impregnated to the molecular bonding material described above for 30 seconds and dried at 120° C., and thus the molecule bonding layer 11 was formed.

Similarly, the heat radiating plate subjected to surface polish was impregnated to the molecular bonding material described above for 30 seconds and dried at 120° C. Then, it was bonded to the ceramic substrate by a heat press of 120° C. and a pressure of 5 MPa, thereby forming a heat radiating plate-lined ceramic substrate as shown in FIG. 1.

Here, with a similar procedure except that Cr electroless plating is introduced before forming the Ni+Cu plating layer, the plating layer can be formed to have a configuration of relaxing the coefficient of thermal expansion, similar to that of the plating layer used in the heat radiating plate-lined ceramic substrate of the third embodiment shown in FIG. 4.

### Example 2

FIG. 11A and FIG. 11B show a process of manufacturing the heat radiating plate-lined ceramic substrate according to the second embodiment shown in FIG. 3.

As the ceramics substrate 1, Si₃N₄ was used, and a Cu plate Cu was used as the heat radiating plate.

As shown in FIG. 11A, the ceramic substrate 1 was subjected to UV irradiation treatment after washing to form a hydroxyl group on the ceramic surface. Thus, the wettability of the aqueous molecular bonding material liquid, which will be described later, was ensured, and the silanol group hydrogen bonding of the molecular bonding material was facilitated.

The molecular bonding material containing an ethoxysilane group, a thiol group and a triazine group was applied and dried as in Example 1, and the molecular bonding material was fixed to the ceramic substrate, thereby obtaining the first bonding layer 2.

The substrate 1 was then subjected to an activation treatment by impregnating it to a plating catalyst liquid a Pd complex for 60 seconds at room temperature, and dried. Thereafter, as shown in FIG. 11A, a plating layer 3-1 comprising 300 nm of Ni layer and 30 nm of Sn layer was formed by nickel electroless plating and Sn electroless plating.

Subsequently, as shown in FIG. 11B, a solder paste was applied to form the solder layer 12, and then as shown in FIG. 3, the heat radiating plate 4 was solder-welded to form the heat radiating plate-lined ceramic substrate 30.

Note that the plating layer can be formed to have appropriate properties by using appropriate material in consideration of workability, solder wettability, corrosion and the like.

### Example 3

A heat radiating plate-lined ceramic substrate according to the fourth embodiment was prepared as follows.

As the ceramics substrate, SiC was used and as the heat radiating plate, a Cu plate was used.

The ceramic substrate was subjected to a corona discharge treatment as in the Example 1 after washing, to form a hydroxyl group on the ceramic surface. Thus, the wettability of the aqueous molecular bonding material liquid, which will be described later, was ensured, and also the silanol group hydrogen bonding of the molecular bonding material was facilitated.

The molecular bonding material was applied and dried as in the Example 1, to fix the molecular bonding material to the ceramic substrate. Thus, a first bonding layer was obtained and thereafter the surface was washed with ethanol to remove the excessive portion of the molecular bonding material.

The substrate was irradiated using UV laser by a grid-like pattern having a pitch of 500 μm and a width of 10 μm, to stop the plating catalyst retention capability of the thiol group on the grid portion.

The substrate was impregnated to a plating catalyst liquid of a Pd colloid for 60 seconds at room temperature and dried. After that, 100 nm of a Ni+Cu plating layer was formed by nickel electroless plating and Cu electroless plating, and the plating layer was grown to be thicker to 5 μm by Cu electrolytic plating.

Then, a solder paste was applied to weld the heat radiating plate, and thus the heat radiating plate-lined ceramic substrate was obtained.

### Example 4

A heat radiating plate-lined ceramic substrate according to the fifth embodiment was prepared as follows.

As the ceramics substrate, AlN was used, and as the heat radiating plate, a Cu plate was used.

The ceramic substrate was subjected to a corona discharge treatment as in the Example 1 after washing, to form a hydroxyl group on the ceramic surface. Thus, the wettability of the aqueous molecular bonding material liquid, which will be described later, was ensured, and also the silanol group hydrogen bonding of the molecular bonding material was facilitated.

The molecular bonding material was applied and dried as in the Example 1, to fix the molecular bonding material to the ceramic substrate. Thus, a first bonding layer was obtained.

The substrate was treated with an SnPd-based plating catalyst liquid to allow Pd to be adsorbed to a molecule bonding agent, followed by drying. Thereafter, 100 nm of a Ni+Cu plating layer was formed by nickel electroless plating and Cu electroless plating, and the plating layer was grown to be thicker to 10 μby Cu electrolysis plating. Then, the plate surface was polished to have a Ra of 0.005 μm.

Similarly, the Cu heat radiating plate polished to comprise a surface having a Ra of 0.005 μm and the polished surface of the plating layer were irradiated with Ar plasma in a vacuum of 5 torr. Then, the heat radiating plate and the ceramic substrate was heated at 250° C. and pressurized at 5 MPa for 20 minutes, thereby attaching the heat radiating plate to the ceramic substrate by solid phase diffusion.

### Example 5

A heat radiating plate-lined ceramic substrate according to the sixth embodiment was prepared as follows.

As the ceramics substrate, SiN was used and as the heat radiating plate, a Cu plate was used.

The ceramic substrate was subjected to a corona discharge treatment as in the Example 1 after washing, to form a hydroxyl group on the ceramic surface. Thus, the wettability of the aqueous molecular bonding material liquid, which will be described later, was ensured, and also the silanol group hydrogen bonding of the molecular bonding material was facilitated.

The molecular bonding material was applied and dried as in the Example 1, to fix the molecular bonding material to the ceramic substrate. Thus, a first bonding layer was obtained.

The substrata was treated with an SnPd-based plating catalyst liquid to allow Pd to be adsorbed to a molecule bonding agent, followed by drying. Thereafter, 100 nm of a Ni+Cu plating layer was formed by nickel electroless plating and Cu electroless plating, and the plating layer was grown to be thicker to 10 μm by Cu electrolysis plating. Then, the plate surface was polished to have a Ra of 0.005 μm.

On top of that, a silicone resin containing a high-thermal conductive fine filler such as of AlN, SiN, Al₂O₃ or BN by 70 to 90% by weight was applied to form a 10 nm-coating layer. After that, a Cu heat radiating plate was disposed on the coating layer, and then heated at 180° C. and pressurized at 5 MPa for 30 minutes, thereby forming a heat conduction stress relaxation layer having a thermal conductivity of 3 to 10 W/mk.

The heat conduction stress relaxation layer transfers heat to absorb the difference in thermal expansion coefficient of the heat radiating plates of SiN (2.6 ppm/° C.) and Cu (16.5 ppm/° C.). Thus, the bonding joining reliability can be ensured.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A heat radiating plate-lined ceramic substrate comprising:
a ceramic substrate;
a first bonding layer on the ceramic substrate;
a plating layer on the first bonding layer; and
a heat radiating plate on the plating layer,
wherein the first bonding layer comprises a molecular bonding material containing a ceramic substrate fixing portion and a plating support portion,
wherein the ceramic substrate and the first bonding layer are bonded together by the ceramic substrate fixing portion, and
wherein the heat radiating plate and the first bonding layer are bonded together by the plating support portion.

2. The ceramic substrate of claim 1, wherein
the ceramic substrate fixing portion comprises a silanol group or a silanol producing group.

3. The ceramic substrate of claim 1, wherein
the plating support portion comprises at least nitrogen.

4. The ceramic substrate of claim 1, wherein
the plating support portion comprises an amino group.

5. The ceramic substrate of claim 3, wherein
the plating support portion comprises an azido group.

6. The ceramic substrate of claim 3, wherein
the plating support portion comprises a triazine ring.

7. The ceramic substrate of claim 1, wherein
the plating support portion comprises at least sulfur.

8. The ceramic substrate of claim 7, wherein
the plating support portion comprises a thiol group.

9. The ceramic substrate of claim 1, wherein
a second bonding layer between the plating layer and the heat radiating plate.

10. The ceramic substrate of claim 9, wherein
the second bonding layer is a solder or a brazing filler metal.

11. The ceramic substrate of claim 9, wherein
the second bonding layer comprises a molecular bonding material same as that of the first bonding layer.

12. The ceramic substrate of claim 1, wherein
a surface of the plating layer is subjected to a flattening process.

13. The ceramic substrate of claim 12, wherein
the flattening process is polishing.

14. The ceramic substrate of claim 12, wherein
the flattening process is rolling.

15. The ceramic substrate of claim 1, wherein
the first bonding layer is patterned.

16. The ceramic substrate of claim 1, wherein
the first bonding layer has a pattern which subdivides a plated region.

17. The ceramic substrate of claim 1, wherein
the plating layer is a multilayered plating layer.

18. The ceramic substrate of claim 17, wherein
the multilayered plating layer has a thermal expansion structure which relaxes a difference in thermal expansion between the ceramic substrate and the heat radiating plate.
